(19) United States
(12) Patent Application Publication
(10) Pub. No.: US 2026/0328490 A1
(43) Pub. Date: Oct. 22, 2026

(54) HEAT SPREADER

(71) Applicant: SIMON FRASER UNIVERSITY, Burnaby (CA)

(72) Inventors: Majid BAHRAMI, North Vancouver (CA); Callum CHHOKAR, Burnaby (CA)

(21) Appl. No.: 19/105,676

(22) PCT Filed: Aug. 22, 2023
(86) PCT No.: PCT/CA2023/051108

§ 371 Date: Feb. 21, 2025

Related U.S. Application Data
(60) Provisional application No. 63/399,864, filed on Aug. 22, 2022.

(51) Int. Cl. F28D 15/04; F28D 15/02

(52) U.S. Cl. CPC F28D 15/04; F28D 15/0241; F28D 15/043

(57) ABSTRACT

A heat pipe that includes an evaporator configured to evaporate fluid to a vapor phase therein in response to heat input, a condenser configured to cause the fluid to condense the fluid to a liquid phase therein, a vapor conduit fluidly coupling an evaporator discharge port to a condenser supply port to transport the fluid in the vapor phase from the evaporator to the condenser, and a liquid conduit fluidly coupling a condenser discharge port to an evaporator supply port to transport the fluid in the liquid phase from the condenser to the evaporator. The evaporator, the condenser, the vapor conduit, and the liquid conduit, together form an elastically deformable and hermetically sealed loop for the flow of the fluid therethrough.

### FIELD OF TECHNOLOGY

The present disclosure relates to heat spreaders, for example, for use in heat management in electronic devices.

### BACKGROUND

Passive heat conductive members, or heat spreaders, are widely used in consumer electronics to dissipate heat from heat sources, where heat builds up in spots or areas, to heat sinks, i.e., ambient. Such heat spreaders include, for example, flat plates or sheets that utilize thermal conductivity for moving heat away from the heat sources. The amount of heat that is transported away from the heat source utilizing such plates or sheets is limited, however, by the thermal conductivity of the plates or sheets.

Other heat spreaders include two-phase flow solutions of heat pipes and vapor chambers. Two-phase heat spreaders utilize a fluid within the heat pipe and vapor chamber. The fluid is heated and vaporized by the heat from the heat source, travels to a condenser, is liquefied, and returns to the heat source. Although such heat spreaders generally exhibit better thermal conductivities than that of flat plates or sheets, the dissipation of heat is inhibited by the resistance to movement of the two phases travelling in opposite directions.

Loop heat pipes, which include separate flow lines for the liquid and vapor phases, are advantageous. Such dedicated flow lines improve internal flow and, subsequently, heat dissipation.

Advances in sensing capabilities in wearable technologies, such as smartwatches, virtual reality equipment, and gloves, result in even larger amounts of heat dissipated to ensure thermal comfort and usability. Heat spreaders are useful for transferring this heat to the ambient in areas of less sensitivity, alleviating thermal comfort concerns.

Such technologies may have different constraints depending on the application. Such constraints include, for example, the large amount of heat dissipation required, size constraints, relative motion of parts of the devices as well as locations of heat sources, and the potential for interference with communications to and from as well as within such devices. Such constraints render the prior art heat transport devices unsuitable in some applications.

Improvements in devices utilized for heat management in electronic devices is desirable.

### SUMMARY

According to one aspect of an embodiment, a heat pipe is provided. The heat pipe includes an evaporator configured to evaporate fluid to a vapor phase therein in response to heat input, a condenser configured to cause the fluid to condense the fluid to a liquid phase therein, a vapor conduit fluidly coupling an evaporator discharge port to a condenser supply port to transport the fluid in the vapor phase from the evaporator to the condenser, and a liquid conduit fluidly coupling a condenser discharge port to an evaporator supply port to transport the fluid in the liquid phase from the condenser to the evaporator. The evaporator, the condenser, the vapor conduit, and the liquid conduit, together form an elastically deformable and hermetically sealed loop for the flow of the fluid therethrough.

According to an aspect of another embodiment, a heat spreader is provided. The heat spreader includes a first ceramic body member, a second ceramic body member joined to the first ceramic body member such that a hermetically sealed space is defined between the first ceramic body member and the second ceramic body member, and a working fluid disposed in a fraction of the volume of the hermetically sealed space to facilitate the spreading of heat. The first ceramic body member includes a first wicking structure formed in an interior surface of the first ceramic body member.

### BRIEF DESCRIPTION OF THE DRAWINGS

Embodiments of the present disclosure will now be described, by way of example only, with reference to the attached figures, in which:

FIG. 1 is a sectional view of a heat pipe in accordance with an aspect of an embodiment;

FIG. 2 is an exploded view of the heat pipe of FIG. 1;

FIG. 3 is a sectional view of an example of an evaporator of the heat pipe of FIG. 1;

FIG. 4 is a sectional view of another example of an evaporator of a heat pipe;

FIG. 5 is a sectional view of an example of a condenser of a heat pipe;

FIG. 6 is a magnified view of a portion of the condenser of FIG. 5;

FIG. 7 is a sectional side view of the heat pipe of FIG. 1;

FIG. 8 is a perspective view of a heat pipe showing hidden detail in accordance with another embodiment;

FIG. 9 is a sectional side view of the heat pipe of FIG. 8;

FIG. 10 is a perspective view of a heat pipe in accordance with another embodiment;

FIG. 11 is a perspective view of the heat pipe of FIG. 10 drawn in a linear configuration and showing hidden detail;

FIG. 12 is a side view of the heat pipe of FIG. 11, showing hidden detail;

FIG. 13 is a sectional view of the heat pipe taken along the line 13-13 of FIG. 12;

FIG. 14 is a sectional view of the heat pipe taken along the line 14-14 of FIG. 12;

FIG. 15 is a perspective view of yet another embodiment of a heat pipe;

FIG. 16 is a perspective view of the heat pipe of FIG. 15, drawn in a linear configuration and showing hidden detail;

FIG. 17 is a side view of the heat pipe of FIG. 16, showing hidden detail;

FIG. 18 is a sectional view of the heat pipe, taken along the line 18-18 of FIG. 17;

FIG. 19 is a sectional view of the heat pipe, taken along the line 19-19 of FIG. 17;

FIG. 20 an exploded perspective view of a two-phase heat pipe in accordance with an embodiment;

FIG. 21 is a side view of the two-phase heat pipe of FIG. 20;

FIG. 22 is a sectional view of the two-phase heat pipe, taken along the line 22-22 of FIG. 21;

FIG. 23 is a sectional view of the two-phase heat pipe, taken along the line 23-23 of FIG. 21;

FIG. 24 is an exploded perspective view of a two-phase heat spreader in accordance with yet another embodiment;

FIG. 25 is a top view of a two-phase heat spreader in accordance with still another embodiment, showing hidden detail;

FIG. 26 is an SEM micrograph showing a cross-sectional view of a green body including a wicking structure formed therein; and

FIG. 27 is a graph showing experimental results of thermal testing of a heat spreader according to an embodiment.

### DETAILED DESCRIPTION

For simplicity and clarity of illustration, reference numerals may be repeated among figures to indicate corresponding or analogous elements. Numerous details are set forth to provide an understanding of the examples described herein. The examples may be practiced without these details. In other instances, well-known methods, procedures, and components are not described in detail to avoid obscuring the examples described. The description is not to be considered as limited to the scope of the examples described herein.

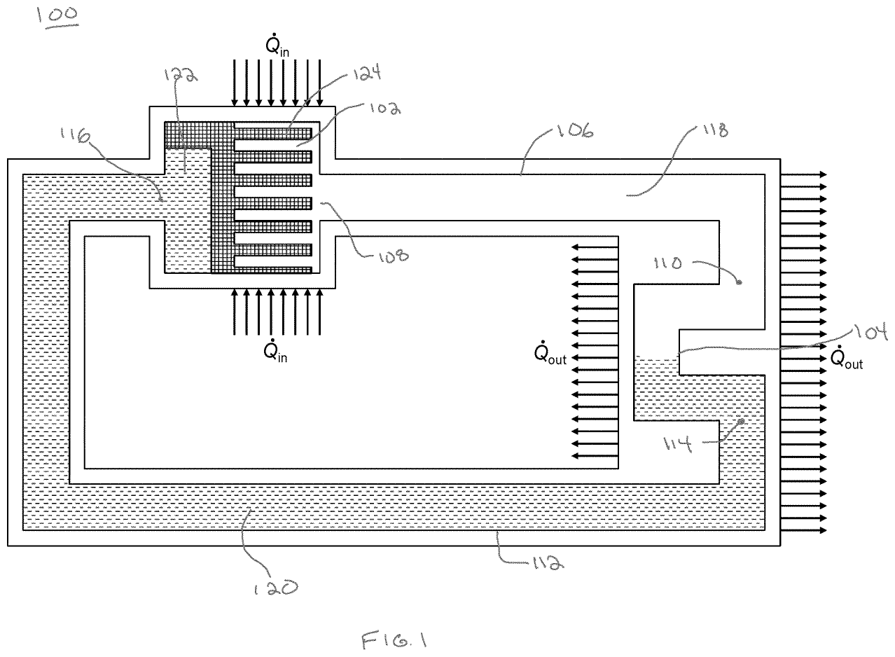

Reference is first made to FIG. 1, which shows an example of a heat pipe 100, which in this example is a loop heat pipe, that includes an evaporator 102 configured to evaporate fluid to a vapor phase therein in response to heat input, a condenser 104 configured to cause the fluid to condense the fluid to a liquid phase therein, a vapor conduit 106 fluidly coupling an evaporator discharge port 108 to a condenser supply port to transport the fluid in the vapor phase from the evaporator 102 to the condenser 104, and a liquid conduit 112 fluidly coupling a condenser discharge port 114 to an evaporator supply port 116 to transport the fluid in the liquid phase from the condenser 104 to the evaporator 102. The evaporator 102, the condenser 104, the vapor conduit 106, and the liquid conduit 112, together form an elastically deformable and hermetically sealed loop for the flow of the fluid therethrough.

The evaporator 102 of the heat pipe 100 may be fixed to a heat-generating component in an electronic device, which may be any suitable electronic device such as a smartwatch, a virtual or mixed reality headset, a smartphone, or any other suitable electronic device. The condenser 104 may be coupled to a heat-removing component fixed on the electronic device such as a heat sink.

A working fluid is contained in the closed loop in a vapor phase 118 and a liquid phase 120. An excess or reserve amount of the liquid phase 120 of the fluid is stored in a compensation chamber 122 to continually wet a wicking member 124 within the evaporator 102. The fluid may be any suitable fluid for cooling the heat generating component utilizing the latent heat of vaporization. A fluid with high vapor pressure and high latent heat of vaporization is advantageous. For example, the fluid may be water or may be an alcohol. Vapor is generated at the evaporator 102 and flows through the vapor conduit 118 to the condenser 104. The vapor is then condensed at the condenser 110, removing the heat generated at the evaporator 102. The liquid is returned to the evaporator 108 through the liquid conduit 112.

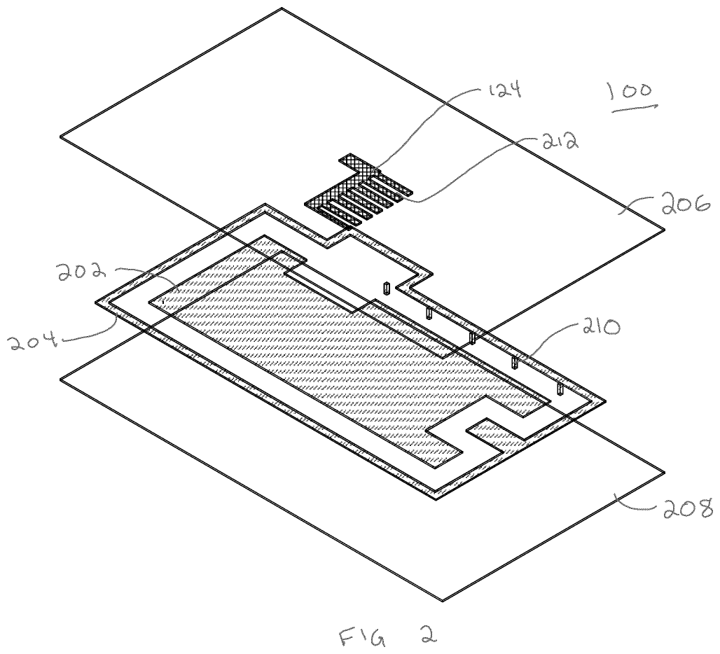

Reference is made to FIG. 2 with continued reference to FIG. 1. FIG. 2 shows an exploded view of the heat pipe 100 of FIG. 1. In this example, the heat pipe 100 includes a plate-type evaporator 102 and condenser 104, with the vapor conduit 106, the liquid conduit 112, and the evaporator discharge port 108 and evaporator supply port 116 defined by flat-plate inserts 202, 204, An outer insert 204 defines an outer side of heat pipe 100, including the evaporator 102, condenser 104, vapor conduit 106, and liquid conduit 112. An inner insert 202 defines an inner side of the heat pipe 100, including the evaporator 102, condenser 104, vapor conduit 106, and liquid conduit 112.

The inner insert 202 and the outer insert 204 are disposed between two body members, referred to herein as the first body member 206 and the second body member 208. The first body member 206 and the second body member 208 are made of elastically flexible material that provides a seal, acting as a gas barrier. The elastically flexible material is elastically deformable for many cycles without exhibiting permanent deformation such as wrinkles or creases. The elastically flexible material is suitable for providing a barrier to the working fluid, and for application of a vacuum, for example, <10⁻⁵ torr, and high-temperatures in excess of 100 °C. The elastically flexible material exhibits low or no outgassing, for example, total mass loss<1%, and is configured to, when hermetically bonded to the inner insert 202 and the outer insert 204, hold a vacuum of <10⁻⁵ torr for several years with subjecting to a high operating temperature in excess of 100 °C. Suitable materials for the first body member 206 and the second body member 208 include, for example, nonporous ceramics, ceramic-coated polymers, graphite sheets and their derivatives or treated graphite sheets, graphene sheets and their derivatives, and metalized films as laminates. In one example, a polymer layer may be utilized to facilitate deformation while a ceramic layer on the polymer layer is utilized as a gas barrier. The ceramic layer may be deposited on the polymer layer by vapor deposition or atomic layer deposition, for example.

The evaporator 102 may be comprised of electrically insulating material. In the present example, the first body member 206, the second body member 208, the inner insert 202 and the outer insert 204 are made of an electrically insulating material to reduce the chance of interference with components of the electronic device that the heat pipe 100 is utilized with. Thus, the components including the evaporator 102, the condenser 104, the vapor conduit 106, and the liquid conduit 112 are each comprised of electrically insulating material.

The inner insert 202 and the outer insert 204 are bonded to the first body member 206 and to the second body member 208 without an intermediary layer via surface activation. The surface activation is a treatment that alters the surface to facilitate direct bonding, without the use of adhesive such as glue, epoxy, or glass frit.

The inner insert 202 and the outer insert 204 are made of elastically flexible material, suitable for the containing the working fluid. Like the first body member 206 and the second body member 208, the inner insert 202 and the outer insert 204 are made of elastically flexible material that is pliable through many cycles of elastic deformation without exhibiting permanent deformation, i.e., wrinkling, creasing, or collapsing. The inner insert 202 is suitable for application of a vacuum, but the channel insert is internal to the hermetic enclosure and exhibits little or no outgassing, for example, a total mass loss<1%, to inhibit the introduction of gas to the system over time. While the first body member 206 and the second body member 208 provide a gas barrier, the inner insert 202 may not be near-perfect gas barrier.

The wicking member 124 is made of wettable, elastically flexible material, for storing the liquid phase 120 of the fluid and enhancing vapor formation at the evaporator 102. The wicking member 124 is hydrophilic, or wettable, with a water contact angle of less than 90 ° and pores smaller than the capillary length of the liquid phase 120 of the fluid. As with other components internal to the heat pipe 100, the wicking member 124 exhibits little or no outgassing having a total mass loss<1%, and is suitable for use with the fluid and at relatively high-temperature of >100 °C. The wicking member 124 may include for example, a layered mesh, porous media, grooves, or a combination thereof.

A support structure 210 is included in the vapor conduit 106 to inhibit collapse of the vapor conduit 106 upon evacuation. In the present example, the support structure 210 includes an array of pillars or spacers that are made of elastically flexible material. The pillars are directly bonded to the first body member 206 and to the second body member 208 without an intermediary layer. Alternatively, a wall or insert may be utilized as a support structure rather than the pillars.

In this example, the evaporator 102 includes the compensation chamber 122. The evaporator 102, including the compensation chamber 122 is formed by the first body member 206, the second body member 208, the inner insert 202, and the outer insert 204. The compensation chamber 122 receives the fluid in the liquid phase prior to evaporation. The wicking member 124 is wetted by the fluid received in the compensation chamber. The wicking member is positioned within the evaporator 102, and includes grooves 212 near the evaporator discharge port 108. The wicking member 124 is bonded to the first body member 206 and the second body member 208.

Alternatively, the compensation chamber may be separate of the evaporator and in fluid communication with the evaporator to receive the fluid in the liquid phase prior to introduction to the evaporator.

Referring to FIG. 3, an alternative example of an evaporator 102 including a wicking member 124 is shown. The wicking member 124 includes the grooves 212. The wicking member 124 in the present example is a woven fibrous wicking member that is surface treated, for example, by atomic layer deposition, to provide a highly wettable, referred to as superhydrophilic, wicking member 124. As indicated above, the woven fibrous wicking member 124 exhibits little or no outgassing having a total mass loss<1%, and is suitable for use with the fluid and at relatively high-temperature of >150 °C.

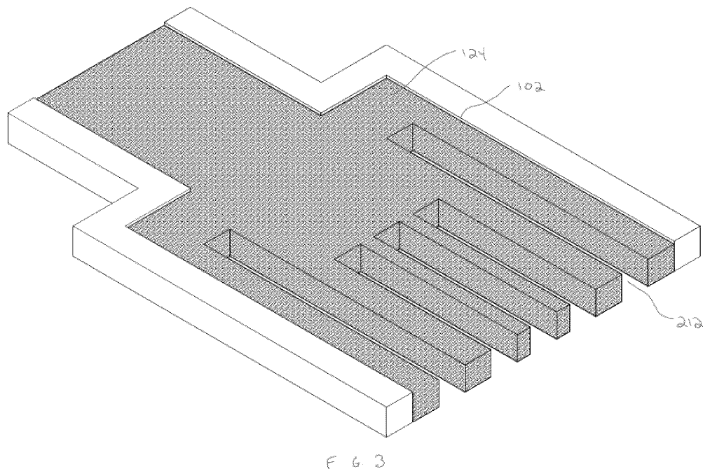

Referring now to FIG. 4, another alternative example of an evaporator 102 including a wicking member 124 is shown. In the example shown in FIG. 4, the wicking member 124 is wettable and nonporous. The wicking member 124 may be an insert or may be printed, bonded, or machined into one or both of the first body member 206 and the second body member 208. The wicking member shown in FIG. 4 includes longitudinal grooves 402 in a portion of the wicking member 124 that is adjacent the evaporator supply port 116, and perpendicular grooves 404, i.e., perpendicular to the grooves 212 formed in the wicking member 124. The compensation chamber 122 includes the portion of the wicking member 124 that has the longitudinal grooves 402. As with the example described with reference to FIG. 3, the wicking member is surface treated, for example, by atomic layer deposition, to provide a highly wettable, or superhydrophilic, wicking member 124. Again, the woven fibrous wicking member 124 exhibits little or no outgassing having a total mass loss<1%, and is suitable for use with the fluid and at relatively high-temperature of >150 °C.

Referring again to FIG. 1 and FIG. 2, the condenser 104 is also formed by the first body member 206, the second body member 208, the inner insert 202, and the outer insert 204 that together form a serpentine cavity, which is the condenser 104.

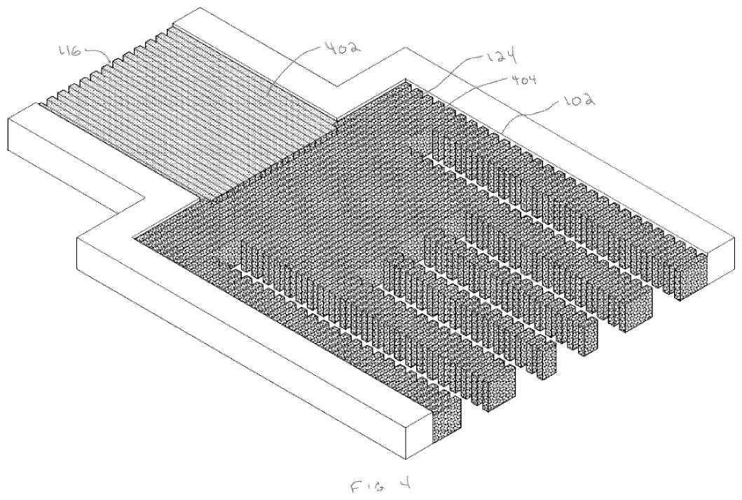

Referring to FIG. 5, an example of a condenser 104 is shown. In this example, the condenser 104 is surface-treated to provide a superhydrophobic and slippery serpentine channel, having a water contact angle>150 degrees and a contact angle hysteresis<5 degrees.

The treatment is suitably durable to last the lifetime of the electronic device that the heat pipe 100 is utilized with. As shown in the magnified view of FIG. 6, the serpentine channel includes asymmetric bumps 602. The surface treatment is selected to exhibit little or no outgassing having a total mass loss<1%, and suitable surface adhesion.

Referring again to FIG. 1 and FIG. 2, the liquid conduit 112 is also formed by the first body member 206, the second body member 208, the inner insert 202, and the outer insert 204. The liquid conduit 112 is capillary-sized to facilitate capillary action that drives the flow of the working fluid in the liquid conduit 112 to return liquid to the evaporator supply port 116, providing the liquid to the evaporator. The liquid conduit 112 may include surface features that facilitate wicking or capillary action. For example, the liquid conduit 112 may include grooves, a porous wicking member, a hierarchical structure, or combination of these features. A hierarchical structure may include features having different scales, for example, micro and nano-scale features, or may include layers having different features.

The vapor conduit 106 is formed by the first body member 206, the second body member 208, the inner insert 202, the outer insert 204, and the support structure 210. The vapor conduit 106 is larger than the liquid conduit 112, to provide lower flow resistance. The support structure 210 within the vapor channel inhibits collapse of the vapor conduit 106.

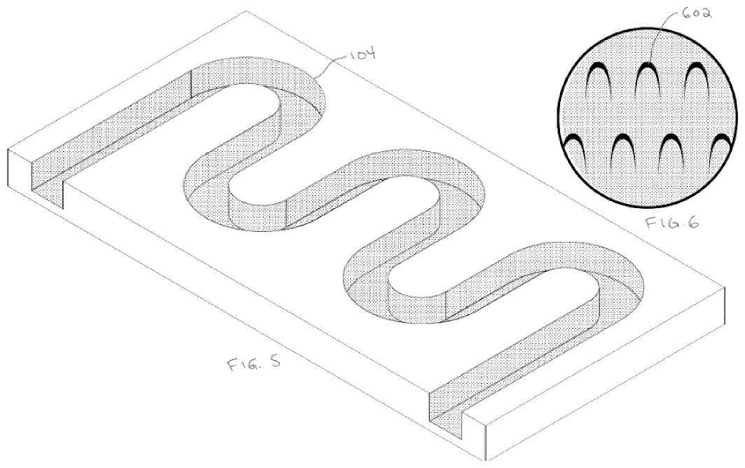

FIG. 7 shows a sectional view of the heat pipe 100, taken along the line 7-7 and drawn to a larger scale. The sectional view shows the first body member 206 and the second body member 208 as well as the inner insert 202 and outer insert 204 that together form the vapor conduit 106 and the liquid conduit 112 in the present example.

The heat pipe 100, including each of the evaporator, condenser, vapor conduit, and liquid conduit are elastically deformable to provide a heat pipe that has a minimum bend radius of 50 mm, i.e., capable of elastic deformation to a bend radius of 50 mm. While all parts may exhibit elastic flexibility, the vapor conduit and liquid conduit may be configured to facilitate greater elastic deformation than the evaporator or the condenser. For example, the vapor conduit and liquid conduit may have a minimum bend radius of 10 mm.

In use, the evaporator 102 is thermally coupled to a heat-generating electronic component, such as an electronic central processing unit (CPU). The fluid in the evaporator 102 absorbs heat from the electronic component and is vaporized, generating vapor pressure. The vapor travels to and is cooled at the condenser 104, generating a lower vapor pressure than the vapor pressure at the evaporator discharge port 108 of the evaporator 102. Thus, a vapor pressure gradient is provided that drives the flow in the vapor conduit. Vapor is condensed into liquid at the condenser 104. The liquid flows back to the evaporator 102 through the liquid conduit 112 and into the evaporator supply port 116.

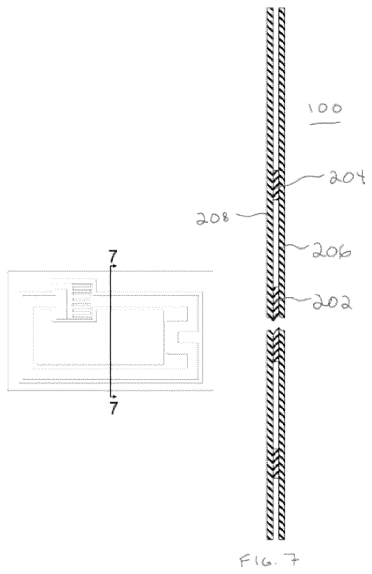

Another example of a heat pipe is shown in FIG. 8. Again, the heat pipe shown in FIG. 8 is a loop heat pipe and includes many elements with similar functions to those described above with reference to FIG. 1. Similar reference numerals are used herein in referring to FIG. 8, raised by 700.

Thus, the heat pipe shown in FIG. 8 is indicated generally by the numeral 800. In this example, the heat pipe 800 includes a plate-type evaporator 802 and plate-type condenser 804. The vapor conduit 806 and liquid conduit 812 are generally tubular conduit members. The vapor conduit 806 fluidly couples an evaporator discharge port 808 to a condenser supply port 810 to transport the fluid in the vapor phase from the evaporator 802 to the condenser 804. The liquid conduit 812 fluidly couples a condenser discharge port 814 to an evaporator supply port 816 to transport the fluid in the liquid phase from the condenser 804 to the evaporator 802.

In this example, the evaporator 802 includes a compensation chamber 822. The evaporator 802 is formed by a first evaporator body member 828 and a second evaporator body member 830, as well as an evaporator insert 826 disposed between the first evaporator body member 828 and the second evaporator body member 830.

The wicking member 824 is positioned within the evaporator 802, and includes grooves 832 near the evaporator discharge port 808. The wicking member 824 is bonded to the first evaporator body member 828 and the second evaporator body member 830.

As with other components internal to the heat pipe 800, the wicking member 824 exhibits little or no outgassing having a total mass loss<1%, and is suitable for use with the fluid and at relatively high-temperature of >100 °C. The wicking member 824 may include for example, a layered mesh, a porous media, or may be grooves in a non-porous insert or formed directly in one or both of the first evaporator body member 828 and a second evaporator body member 83, or a combination thereof.

The evaporator 802 is sealed with an intermediary layer of vacuum sealant, such as glue, epoxy, or glass frit. The intermediary layer may be utilized around the outer edges of the evaporator 802 to provide the seal at the edges and at the evaporator discharge port 808 and the evaporator supply port 816 where the evaporator 802 is coupled to the vapor conduit 806 and to the liquid conduit 812.

The condenser 804 includes a first condenser body member 834 and a second condenser body member 836, as well as a condenser insert 838 disposed between the first condenser body member 834 and the second condenser body member 836. The condenser 804 is also hermetically sealed with an intermediary layer at the edges and at the condenser discharge port 814 and the condenser supply port 816 where the condenser 804 is coupled to the vapor conduit 806 and to the liquid conduit 812.

The vapor conduit 806 and the liquid conduit 812 are both made of elastically flexible material and that inhibits collapse upon evacuation. The vapor conduit 806 and the liquid conduit 812 are made of elastically flexible material that is pliable through many cycles of elastic deformation without exhibiting permanent deformation, i.e., wrinkling, buckling, creasing, or collapsing. The elastically flexible material exhibits little or no outgassing, for example, a total mass loss<1% and provides a gas barrier, i.e., is impervious to the vapor. When the vapor conduit 806 and the liquid conduit 812 are coupled to the evaporator 802 and to the condenser 804 by hermetic seals, the vapor conduit 806 and the liquid conduit 812, as well as the couplings to the evaporator 802 and to the condenser 804 are configured to hold a vacuum of <10⁻⁵ torr for several years with subjecting to a high operating temperature in excess of 100 °C.

A sectional view of the heat pipe 800, taken along the line 9-9 and drawn to a larger scale, is shown in FIG. 9. The sectional view extends through the vapor conduit 806 and the liquid conduit 812. The vapor conduit 806 may include a support structure 902 such as a flexible mesh that is inserted into the vapor conduit 806. The liquid conduit 812 may include a wicking member 904 such as a layered mesh that is inserted into the liquid conduit 812 and wicks liquid from the condenser 804 to the evaporator 802.

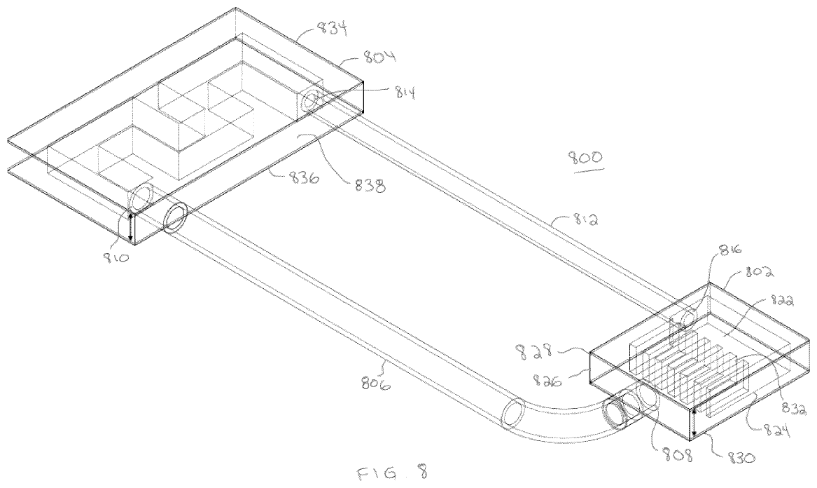

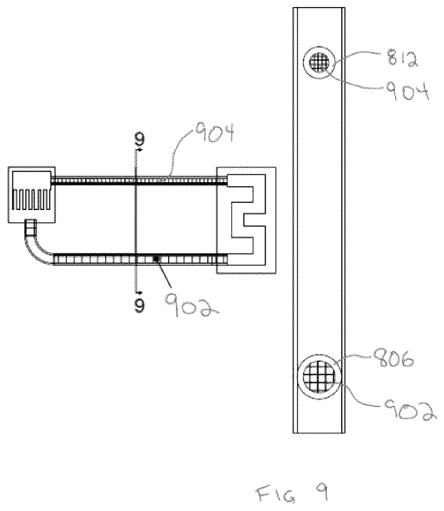

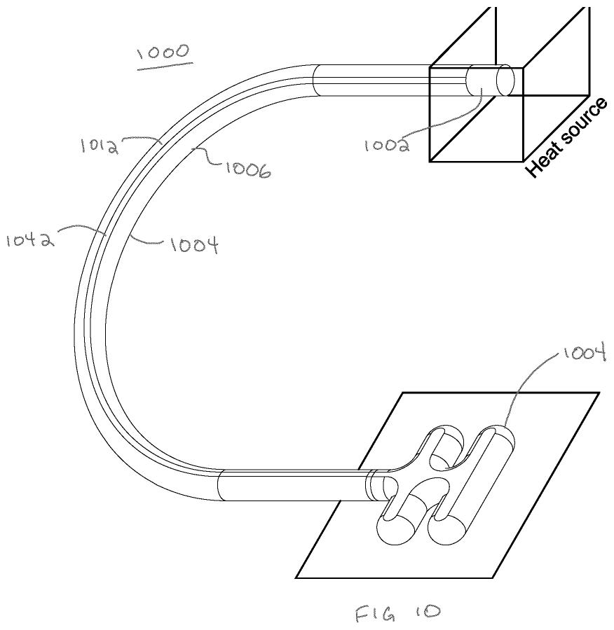

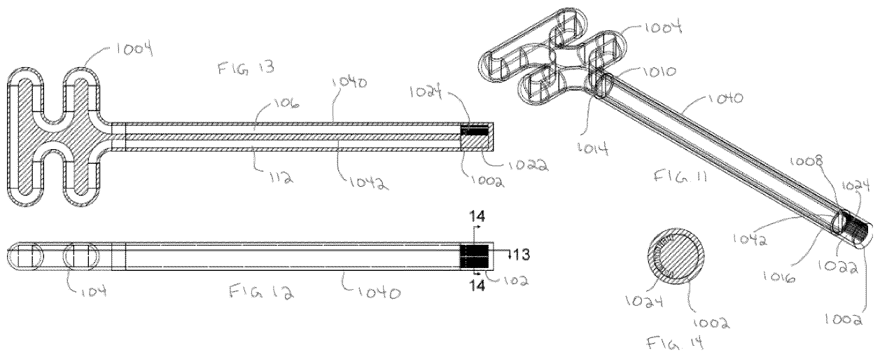

Another example of a heat pipe is shown in FIG. 10 through FIG. 14 and indicated generally by the numeral 1000. The heat pipe 1000 includes many elements with similar functions to those described above with reference to FIG. 1. Similar reference numerals are used herein in referring to FIG. 10, raised by 900.

In the present example, the heat pipe 1000 includes a cylindrical evaporator 1002 and a finned condenser 1004. The vapor conduit 1006 and the liquid conduit 1012 are comprised of a single duct 1040 separated into the vapor conduit 1006 and the liquid conduit 1012 by an insulating spacer 1042 that runs lengthwise along the duct 1040. Thus, one half of the duct 1040 is the vapor conduit 1006 and the other half of the duct 1040 is the liquid conduit 1012.

The evaporator 1002 includes a compensation chamber 1022. The evaporator 1002 is sealed with an intermediary layer of vacuum sealant, such as glue, epoxy, or glass frit. The intermediary layer may be utilized around the outer edges of the evaporator 1002 to provide the seal at the edges and at the evaporator discharge port 1008 as well as the evaporator supply port 1016. The condenser 1004 is also hermetically sealed with an intermediary layer at the edges and at the condenser supply port 1010 as well as the condenser discharge port 1014.

The cylindrical evaporator 1002, which includes the compensation chamber 1022, houses a wicking member 1024 within the sealed evaporator 1002. The wicking member 1024 is bonded within the cylindrical evaporator 1002. The cylindrical evaporator 1002 is coupled to and hermetically sealed with the vapor conduit 1006 and the liquid conduit 1012. The cylindrical evaporator 1002 may include tubing with the internal wicking member inserted or molded therein utilizing sacrificial materials that facilitate the creation of complex or hollow structures.

The finned condenser 1004 is molded to provide the finned structure and configured to provide a serpentine fluid flow channel with many turns. For example, the finned condenser 1004 may be molded utilizing sacrificial materials. The finned condenser 1004 is coupled to and hermetically sealed with the vapor conduit 1006 and the liquid conduit 1012. Together, the components of the heat pipe 1000 are hermetically sealed and configured to hold a vacuum of <10⁻⁵ torr for several years.

The duct 1040 may be molded of, for example, polymer, ceramic or other elastically flexible material or fabricated using additive manufacturing with the insulating spacer 1042 therein to divide the duct 1040 into the vapor conduit 106 and the liquid conduit 112. The duct 1040 is made of elastically flexible material and that inhibits collapse upon evacuation. The duct 1040 and the insulating spacer 1042 are made of elastically flexible material that is pliable through many cycles of elastic deformation without exhibiting permanent deformation, i.e., wrinkling, creasing, or collapsing. The elastically flexible material exhibits little or no outgassing, for example, a total mass loss<1%, and provides a gas barrier, i.e., is impervious to the vapor. When the vapor conduit 1006 and the liquid conduit 1012 are coupled to the evaporator 1002 and to the condenser 1004 by a hermetic seal, the vapor conduit 1006 and the liquid conduit 1012, as well as the couplings to the evaporator 1002 and to the condenser 1004 are configured to hold a vacuum of <10 ⁻⁵ torr for several years with subjecting to a high operating temperatures in excess of 100 °C.

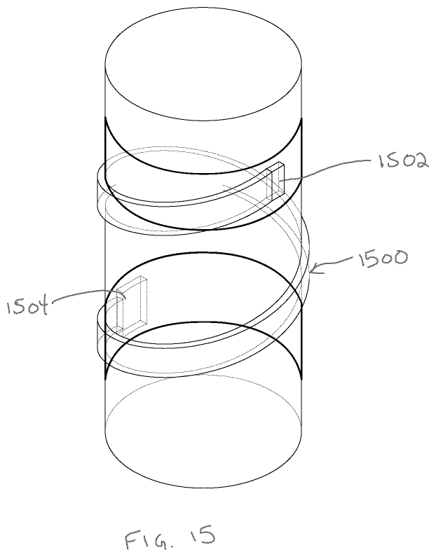

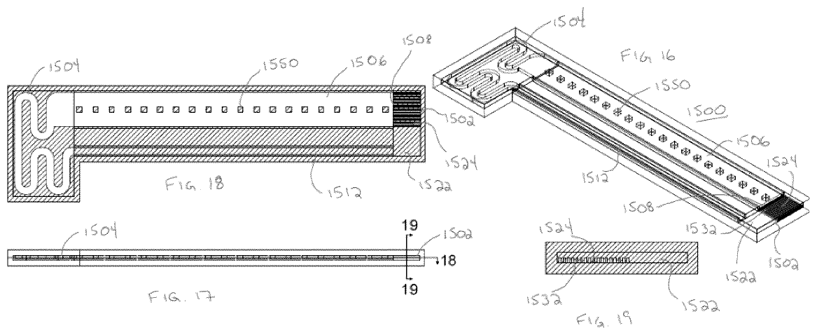

Yet another example of a heat pipe is shown in FIG. 15 through FIG. 19 and indicated generally by the numeral 1500. Similar reference numerals to those used in reference to FIG. 1 are used herein, raised by 1400 to denote elements with similar function to those described with reference to FIG. 1. In the present example, the heat pipe 1500 includes a molded plate-type evaporator 1502 and condenser 1500, which may be molded utilizing sacrificial molds, and are made of elastically flexible materials such as polymers, metallic laminate, or ceramic In this example, the heat pipe 1500 is very flexible in three dimensions such that the heat pipe is configurable to wrap around or over an structure and conform to the surface of the structure while inhibiting collapse or kinking of the vapor conduit 1506 and the liquid conduit 1512.

The components of the heat pipe 1500, including the evaporator 1502 and condenser 1504 as well as the vapor conduit 1506 and the liquid conduit 1512, exhibit little or no outgassing, for example, total mass loss<1%. The evaporator 1502 and condenser 1504 as well as the vapor conduit 1506 and the liquid conduit 1512 are hermetically sealed and are configured to hold a vacuum of <10⁻⁵ torr for several years with subjecting to high operating temperatures in excess of 100 °C.

In this embodiment, the evaporator 1502 includes the compensation chamber 1522 and includes a wicking member 1524. The evaporator 1502, including the compensation chamber 1522, are part of the molded heat pipe 1500. The wicking member 1524 in the present example is molded into the evaporator 1502 and includes a plurality of grooves 1532 near the evaporator discharge port 1508.

The condenser 1504 is also part of the molded heat pipe 1500 and includes an internal serpentine fluid flow channel with many turns.

As in the example described with reference to FIG. 1, the vapor conduit 1506 is larger than the liquid conduit 1512, to provide lower flow resistance. Support structures 1550, which in this example include an array of pillars or spacers, within the vapor conduit 1506 inhibit collapse of the vapor conduit 1506 upon evacuation.

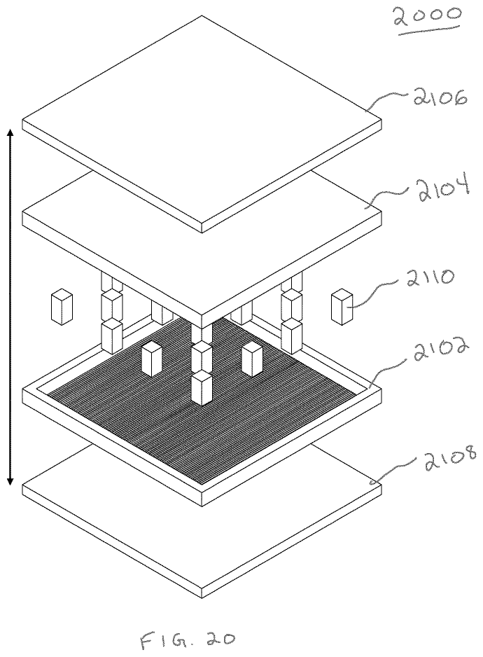

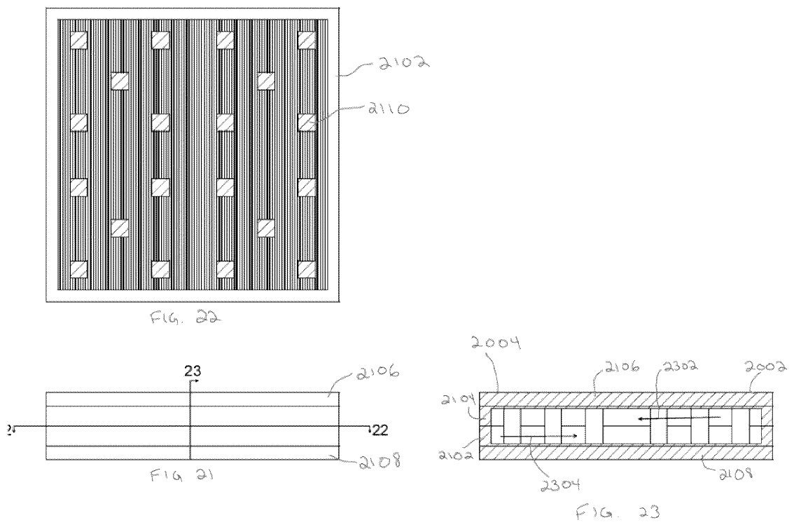

Reference is now made to FIG. 20 through FIG. 23, which illustrates a lined flexible, non-metallic two-phase heat spreader or thermal ground.

Rather than a loop heat pipe, FIG. 20 to FIG. 23 illustrate a flat heat pipe or heat spreader. The flat heat pipe 2000 may be include ceramic body members on which inserts that include grooves or pillars are bonded to create vapor and liquid conduits. The internal surfaces of the polymeric inserts are coated to improve wettability. The edges are sealed to provide the flat heat pipe 2000. The ceramic may be, for example Corning™ glass and may be utilized for applications in which low electromagnetic interference is desirable. Alternatively the flat heat pipe 2000 may be a metal lined polymer for use in applications in which electromagnetic interference is not a consideration.

As illustrated in FIG. 20 through FIG. 23, a first body member 2106 is separated from a second body member 2108 by a first insert 2102 and a second insert 2104. As indicated, the first body member 2106 and the second body member 2108 may be ceramic. The first insert 2102 is a grooved polymeric insert of, for example, polydimethylsiloxane (PDMS), that includes a surface coating, for example, applied by atomic layer deposition, to enhance wettability and act as a gas barrier. Similarly, the second insert 2104 is a grooved polymeric insert of, for example, polydimethylsiloxane (PDMS), that includes a surface coating, for example, applied by atomic layer deposition, to enhance wettability and act as a gas barrier. Optionally, spacers 2110 may be included between the first insert 2102 and the second insert 2104. The spacers may also be polymeric or ceramic. The outer edges of the first body member 2106, the second body member 2108, the first insert 2102, and the second insert 2104 may optionally be sealed utilizing an intermediary layer such as a ceramic frit or epoxy sealant.

Together, the first body member 2106, the second body member 2108, the first insert 2102, and the second insert 2104 provide a vapor chamber or line 2006 and a liquid chamber or line 2012. In the example illustrated, the spacers 2110 provide structural support in the vapor chamber of line 2006. The vapor chamber includes a wicking structure or wicking member, provided by the second insert 2104, or polymeric grooved insert, as well as the spacers 2110 in the vapor chamber. The first insert 2102 also provides a wicking structure or wicking member for the liquid. The heat pipe 2000 is symmetrical in that the first body member 2106 and the second insert 2104 are similar to the second body member 2108 and the first insert 2102.

In use, heat enters an evaporator portion 2002 through the first body member 2106 and the second body member 2108, and the liquid permeating the wicking member absorbs the heat and evaporates. The vapor flows from the evaporator portion as indicated by the arrow 2302, through an adiabatic portion to a condenser portion 2004, where heat is removed from the vapor and the vapor condenses. The condensate permeates the wicking structure and is returned to the evaporator 2002 by capillary pressure as indicated by the arrow 2304, completing the closed-loop thermodynamic cycle.

In this example, the vapor chamber or line 2006 and the liquid chamber or line 2012 are concurrent in that they are stacked on top of each other.

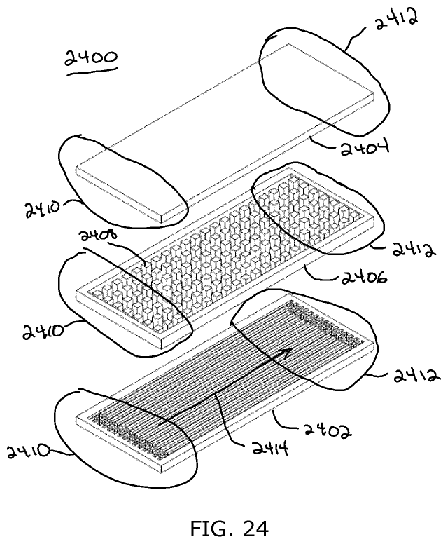

Referring now to FIG. 24, another heat spreader is shown and indicated generally by the reference numeral 2400. In the present example, the heat spreader 2400 is a non-flexible flat heat spreader. The flat heat spreader 2400 is comprised of ceramic body members on which grooves are formed to facilitate wicking of liquid to move the liquid between condenser and evaporator portions of the heat spreader and to spread heat. The ceramic may be, for example, alumina. In one example, the flat heat spreader 2400 is about 5″ (127 mm) long by about 2″ (50.8 mm) wide for use with an electronic device or component. Alternatively, the flat heat spreader may have equal length and width, for example about 2″ (50.8 mm) long and 2″ (50.8mm) wide. Other dimensions may be successfully implemented. The total thickness of the flat heat spreader 2400 with all components may be, for example, about 1.2 to about 1.3 mm. Other thicknesses of flat heat spreaders may be successfully implemented, however.

In this example, a first body member 2402 is separated from a second body member 2404 by a frame spacer 2406 that is sandwiched between an outer margin of the first body member 2402 and an outer margin of the second body member 2404 to provide the sidewalls of the heat spreader 2400. The frame spacer 2406 is of sufficient thickness to provide an internal space between the first body member 2402 and the second body member 2404 for the movement of vapor within the heat spreader 2400. The frame spacer 2406, together with the first body member 2402 and the second body member 2404, are sealed or bonded to provide a hermetically sealed heat spreader 2400.

Additional spacers may also be included between the first body member 2402 and the second body member 2404 to maintain the spacing between the two and inhibit collapse upon evacuation of the structure. In the present embodiment, columnar spacers 2408 are included.

The heat spreader 2400 may be manufactured using a tape casting process for alumina in which an alumina slurry is dried onto a plastic tape to provide green tape. The green tape is machined and punched and may be laminate prior to firing or sintering at about 1600 °C to form fired alumina. The fired alumina is capable of providing a hermetic seal down to thicknesses in the range of about 50 μm to about 250 μm.

As indicated above, the first body member 2402 and second body member 2404 are ceramic, such as alumina. The frame spacer 2406 and the columnar spacers 2408 may also be ceramic such as alumina. All of the elements may therefore be alumina and may be bonded together by firing the components together. Thus, an intermediary layer or bonding layer is not utilized. Carbon black or any other suitable investment material may be inserted to provide and maintain the internal space during manufacture.

A pinch-off tube of, for example, copper may be utilized for evacuating and then filling the resulting heat exchanger structure with the working fluid, which may be water or alcohol, for example. The copper pinch-off tube may be fixed to a preformed opening in one of the first body member 2402 and second body member 2404, by brazing an oxygen-free copper (OFC) tube at a temperature of about 800 °C. The spacers including the columnar spacers 2408 maintain the shape and spacing during evacuation followed by filling of the structure. In one example, the structure may thus be evacuated, for example, to below 7.5×10⁻⁴ torr (0.1 Pascals) and then filled with degassed water to a fill ratio or ratio of liquid volume to volume available within the heat spreader, of about 43%.

The grooves referred to above for wicking may be formed in both the first body member 2402 and the second body member 2404 as well as the surfaces of the frame spacer 2406 and the columnar spacers 2408 that are exposed to the working fluid. For example, 50 μm width grooves that extend a depth of about 100 μm into the surface may be utilized. The 50 μm is well below the capillary length for water to facilitate wicking. The grooves may be formed by laser forming or embossing the alumina tape. Spacing of about 100 μm between edges of adjacent grooves may be utilized. Testing and analysis was carried out and confirmed that such groove geometry is reliably constructed in the alumina and the resulting alumina exhibits suitable wettability and capillary action.

In use, the heat spreader 2400 moves heat away from an electronic component such as a CPU. The heat spreader 2400 may be, for example, disposed on the electronic component to receive heat at an evaporator portion 2410 through the first body member 2402 and the second body member 2404. Liquid that flows by capillary action to the evaporator portion 2410, absorbs the heat and evaporates. The vapor flows from the evaporator portion 2410 as indicated by the arrow 2414, through an adiabatic portion to a condenser portion 2412, where heat is removed from the vapor and the vapor condenses. The condensate permeates the wicking structure, i.e., the grooves in the surface of the first body member 2402 and the grooves in the surface of the second body member 2404, and is returned to the evaporator portion 2410 by capillary action, completing the closed-loop thermodynamic cycle.

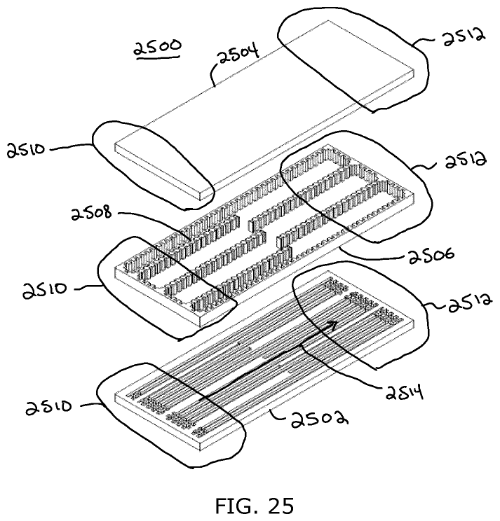

FIG. 25 shows an example of another heat spreader, indicted generally by the numeral 2500. The heat spreader illustrated in FIG. 25 is similar to the heat spreader shown in FIG. 24 and described above. The heat spreader 2500 is a non-flexible, flat heat spreader that includes ceramic body members on which grooves are formed to facilitate wicking of liquid to move the liquid between condenser and evaporator portions of the heat spreader and to spread heat.

Again, the flat heat spreader 2500 may be about 5″ (127 mm) long by about 2″ (50.8 mm) wide for use with an electronic device or component. The total thickness of the flat heat spreader 2500 with all components may be, for example, about 1.2 to about 1.3 mm.

As in the example described above, the heat spreader in this example, a first body member 2502 that is separated from a second body member 2504 by a frame spacer 2506 that is sandwiched between an outer margin of the first body member 2502 and an outer margin of the second body member 2504, to provide the sidewalls of the heat spreader 2500. The frame spacer 2506 is of sufficient thickness to provide an internal space between the first body member 2502 and the second body member 2504 for the movement of vapor within the heat spreader 2500. The frame spacer 2506, together with the first body member 2502 and the second body member 2504, are sealed or bonded to provide a hermetically sealed heat spreader 2500.

In the present example, rather than additional spacers in the form of columnar spacers, the frame spacer 2506 includes spacer fingers 2508 that are part of the frame spacer 2506 and extend into the adiabatic portion of the heat spreader 2500 from opposing outer walls of the frame spacer 2506 at the evaporator portion 2510 and the condenser portion 2512.

The spacer fingers 2508 inhibit collapse by maintaining the spacing between the first body member 2502 and the second body member 2504 upon evacuation of the structure.

As described above, the heat spreader 2500 may be manufactured using a tape casting process for alumina in which an alumina slurry is dried onto a plastic tape to provide green tape. The green tape is machined and punched and may be laminated prior to firing or sintering at about 1600 °C to form fired alumina. The fired alumina is of sufficient thickness to provide a hermetic seal.

Alternatively, the heat spreader 2500 may be manufactured utilizing a tape casting process with aluminum nitride.

As indicated above, the first body member 2402, the second body member 2404, and the frame spacer 2406 may be ceramic such as alumina and may be bonded together by firing the components together. Thus, an intermediary layer or bonding layer is not utilized. A lamination process without the use of an investment material may be utilized. Such a process facilitates the incorporation of the fine wicking structure as referred to herein. In one example, a green-state ceramic, i.e., after drying onto the tape and prior to firing, is bonded utilizing an adhesive such as a polymeric adhesive. Pressure may then be applied at relative low pressure compared to the pressures utilized with suitable investment materials.

Optionally, carbon black or any other suitable investment material may be inserted to provide and maintain the internal space during manufacture. Such an investment material may be utilized with lamination processes such as isostatic and semi-isostatic lamination processes in which pressures of about 3000 psi (about 20.7 MPa) may be utilized.

A pinch-off tube as described above may be utilized to evacuate and then fill the resulting heat exchanger structure with the working fluid.

The grooves referred to above for wicking may be formed in both the first body member 2502 and the second body member 2504 as well as the surfaces of the frame spacer 2506, including the spacer fingers 2508 that are exposed to the working fluid. The grooves may extend the entire length of interior surface of the first body member 2502, from the condenser side to the evaporator side. Similarly, the groove may extend over the entire interior surface of the second body member 2504, from the condenser side to the evaporator side. For example, 50 μm width grooves that extend a depth of about 100 μm into the surface may be utilized. The grooves may be formed by laser forming or embossing the alumina tape. Spacing of about 100 μm between edges of adjacent grooves may be utilized. In addition, the frame spacer 2506, including the spacer fingers 2508 may include grooves that extend between the first body member 2502 and the second body member 2504, to facilitate liquid transport between the first body member 2502 and the second body member 2504. Further grooves that extend along the length of the spacer fingers 2508 and that extend transverse to the grooves referred to above that extend between the first body member 2502 and the second body member 2504, may be included to facilitate wicking of the working fluid toward an evaporator portion 2510.

In use, the heat spreader 2500 moves heat away from an electronic component such as a CPU. The heat spreader 2500 receive heat at an evaporator portion 2510 through the first body member 2502 and the second body member 2504. Liquid that flows by capillary action to the evaporator portion 2510, absorbs the heat and evaporates. The vapor flows from the evaporator portion 2510 as indicated by the arrow 2514, through an adiabatic portion to a condenser portion 2512, where heat is removed from the vapor and the vapor condenses. The condensate permeates the wicking structure, i.e., the grooves in the surface of the first body member 2502 and the grooves in the surface of the second body member 2504, and is returned to the evaporator portion 2510 by capillary action, completing the closed-loop thermodynamic cycle. The grooves in the frame spacer 2506 including the grooves in the spacer fingers 2508 facilitate the movement of the liquid in the evaporator portion 2510, reducing the chance that all the liquid evaporates from one area of the evaporator portion 2510 and a hot spot develops.

The grooves referred to above may be formed in one or both the first body member 2402 and the second body member 2404 in the embodiment described with reference to FIG. 24 and in one or both the first body member 2502 and the second body member 2504 in the embodiment described with reference to FIG. 25. Further, grooves may be included in the frame spacer and columnar spacer or spacer fingers. The grooves may be any suitable shape that facilitates wicking. For example, each groove in a surface of one of the body members, frame spacer, columnar spacers, or spacer fingers may be rectangular in cross-section, trapezoidal, or triangular. In addition, the grooves on the body members may be linear, extending from one side to an opposing side of the heat spreader. Alternatively, the grooves on the body members may extend out radially from a location. Any other suitable pattern of grooves may also be successfully employed to move heat away from a heat source.

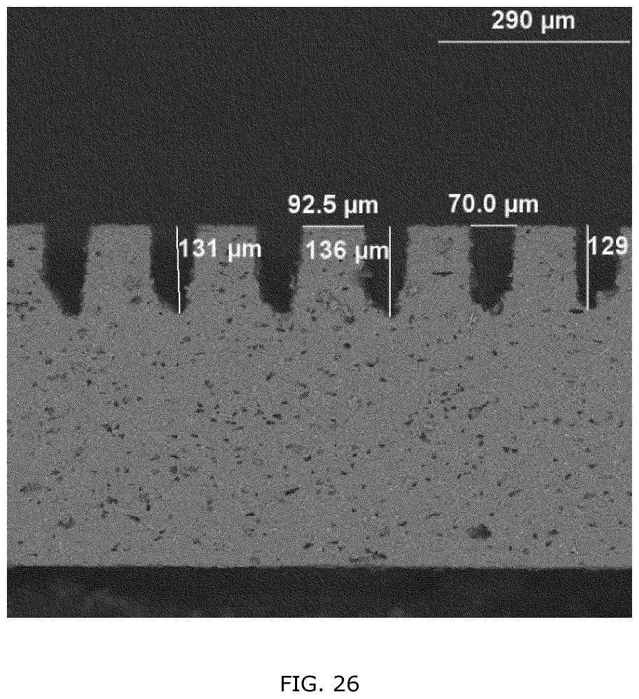

An example cross-section of 6 grooves laser formed in a surface of a green body utilized to form a body member is shown in FIG. 26. As illustrated, the grooves may be generally trapezoidal. In addition, the exact depth, width, and shape of the grooves may vary slightly between the grooves, as shown by the dimensions added to the micrograph, while providing effective wicking.

In the above examples of the flat heat spreaders having the dimensions referred to above of about 5″ (127 mm) length and 2″ (50.8mm) width, the additional spacers may be avoided, i.e., not included, for a heat spreader in which the first and second body members have a thickness greater than about 1 mm. Thus, in such a flat heat spreader, a body member thickness of greater than about 1 mm provides sufficient support to inhibit collapse upon evacuation of the structure. For heat spreaders with a width greater than 2″ (50.8 mm) or heat spreaders with a body member thickness of less than about 1 mm, the spacers described herein and shown in the Figures are utilized to maintain the spacing between the first body member and the second body member.

Rather than directly bonding the ceramic components as described with reference to FIG. 24 and FIG. 25, an intermediary paste may be utilized, such as a glass paste layer that is printed onto fired ceramic components that are then fired together at, for example, about 700 °C and under pressure.

In yet another example, a metallic braze may be utilized as an intermediary layer to bond the ceramic components. The components may be brazed by metallizing the ceramic, for example, using a Mo-Mn (molybdenum-manganese) metallization after firing the ceramic or W (tungsten) metallization may be utilized for firing with the ceramic. A Ag/Cu based or Au/In based braze filler may be utilized at brazing temperature of about 800 °C for example.

Rather than utilizing grooves or a wicking structure, the heat spreader may alternatively be fabricated without such a wicking structure and may utilize gravity for the movement liquid within the heat spreader, thus utilizing the thermosiphon effect.

### EXPERIMENTAL

Thermal testing was conducted utilizing a heat spreader similar to that shown and described above with reference to FIG. 25. The heat spreader utilized during testing, however, did not have grooves or other wicking structure. Instead, the heat spreader was fabricated without a wicking structure and relied on thermosiphon.

Cartridge heaters were utilized on an evaporator portion of the heat spreader and a cooling bath connected to a cold plate was utilized to reject heat from the condenser portion of the heat spreader. T-type thermocouples with an accuracy of ±1 °C were utilized to monitor the evaporator-condenser temperature differential.

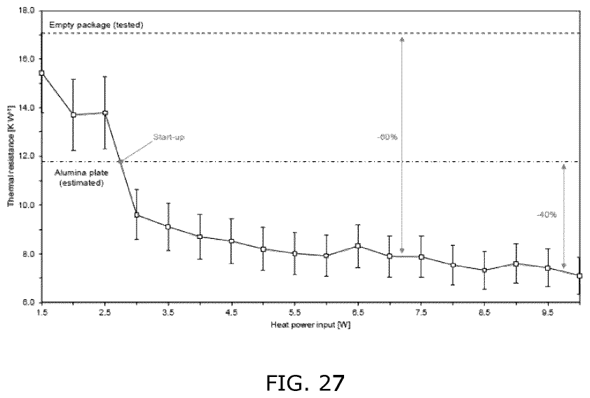

FIG. 27 is a graph showing the experimental results in a plot of thermal resistance v. heat power input. The thermosiphon effect started at about 3W of heat power input and the reached an evaporator temperature of about 95 °C at 10 W. Because the heat spreader is translucent, an LED backlight was utilized to detect localized drying at about 10 W. The heat spreader achieved about a 60% and 40% reduction in thermal resistance compared to experimental results for an uncharged sample and estimates for the thermal resistance achieved utilizing a solid alumina plate, respectively.

The resulting heat spreaders described above with reference to FIG. 24 through FIG. 28 are dielectric and may be mounted directly on an electrical component or components without the risk of electrical shorts. In addition, such heat spreaders are corrosion resistant. Further, the resulting heat spreaders are radio frequency (RF) transparent, i.e., do not interfere with electromagnetic radio waves and therefore suitable for use in microwave, wireless, 6G, and other applications.

In addition, by forming the wicking structure, such as the grooves described above, directly in the body members, the fabrication process is simplified as the structure may be formed with only two firing processes, including one to sinter the alumina and one to braze the pinch-off tube that is utilized for evacuating and adding the working fluid.

Optionally, thermal vias may be formed in one or both of the first body member and the second body member in the heat spreaders described above with reference to FIG. 24 and FIG. 25. The thermal vias may be formed by punching holes in the body member and filling the holes with metal such as tungsten. The filling of the holes may be carried out at the time that the body members are fired, also referred to as sintered. The vias may be soldered to a metallized heat source for spreading heat from the heat source, and to a metallic heat sink.

Optionally, the ceramic may be directly attached by directly bonding to copper, for example, during firing, at a temperature in the range of about 900 °C to 1000 °C. The copper may then be utilized to attach to a metallized heat source and a metallic heat sink. This direct bond to copper may also be utilized around the preformed opening in one of the first body member and second body member for connection to the pinch-off tube. Using this process, copper around the preformed opening may be brazed or soldered to connect the pinch-off tube.

Advantageously, large amounts of heat may be dissipated and moved to locations away from a heat source of an electronic device. In the flexible heat pipe embodiments, the flexibility of the heat pipe facilitates implementation in various locations and applications, while collapse, kinking or creasing or parts is inhibited. In addition, relative movement of, for example, the evaporator and condenser may facilitate relative movement of parts of the electronic device. Further, materials utilized in the heat pipe may be selected to reduce the chance of electrical interference with the electronic devices.

The scope of the claims should not be limited by the embodiments set forth in the examples, but should be given the broadest interpretation consistent with the description as a whole.

1. A heat pipe comprising:
an evaporator configured to evaporate fluid to a vapor phase therein in response to heat input;
a condenser configured to cause the fluid to condense the fluid to a liquid phase therein;
a vapor conduit fluidly coupling an evaporator discharge port to a condenser supply port to transport the fluid in the vapor phase from the evaporator to the condenser; and
a liquid conduit fluidly coupling a condenser discharge port to an evaporator supply port to transport the fluid in the liquid phase from the condenser to the evaporator,
the evaporator, the condenser, the vapor conduit, and the liquid conduit, together forming an elastically deformable and hermetically sealed loop for the flow of the fluid therethrough.

2. The heat pipe according to claim 1, wherein the evaporator is comprised of electrically insulating material.

3. The heat pipe according to claim 2, wherein the condenser, the vapor conduit, and the liquid conduit are each comprised of electrically insulating material.

4. (canceled)

5. The heat pipe according to claim 1, comprising a compensation chamber in fluid connection with the evaporator for receiving the fluid in the liquid phase prior to introduction to the evaporator.

6. (canceled)

7. The heat pipe according to claim 1, wherein the evaporator comprises a body that encloses an internal wicking member.

8. The heat pipe according to claim 1, wherein the condenser comprises a body having an internal serpentine channel.

9. The heat pipe according to claim 8, comprising a surface modification on an internal surface defining the serpentine channel, providing a hydrophobic region.

10. The heat pipe according to claim 1, wherein the liquid conduit comprises a tube or duct having a wicking member disposed therein or a surface patterned to facilitate wicking.

11. (canceled)

12. (canceled)

13. The heat pipe according to claim 1, wherein the vapour conduit comprises a spacer configured to inhibit creasing or collapse of the vapour conduit during deformation.

14. The heat pipe according to claim 1, wherein the evaporator, the condenser, the vapor conduit, and the liquid conduit, comprise a first body member and a second body member, and inserts disposed between the first body member and the second body member.

15. The heat pipe according to claim 14, wherein the first body member, the second body member, and the inserts include a blocking layer to inhibit vapor penetration.

16. The heat pipe according to claim 15, wherein the first body member, the second body member, and the inserts include a polymer layer disposed on the blocking layer and configured to facilitate deformation.

17. (canceled)

18. (canceled)

19. The heat pipe according to claim 7, wherein the internal wicking member comprises a mesh or a fibrous material coupled to the body.

20. (canceled)

21. A heat spreader comprising:
a first ceramic body member;
a second ceramic body member joined to the first body member such that a hermetically sealed space is defined between the first body member and the second body member;
a working fluid disposed in a fraction of the volume of the hermetically sealed space to facilitate the spreading of heat;
wherein the first ceramic body member includes a first wicking structure formed in an interior surface of the first body member.

22. The heat spreader according to claim 21, wherein the first body member and second body member are alumina.

23. The heat spreader according to claim 21, wherein the first body member and the second body member are joined by a frame spacer sandwiched between an outer margin of the first body member and an outer margin of the second body member, providing sidewalls of the heat spreader.

24. The heat spreader according to claim 21, comprising spacers disposed between the first body member and the second body member to maintain a spacing of the first body member from the second body member.

25. The heat spreader according to claim 21, wherein the second body member includes a second wicking structure formed in an interior surface of the second body member.

26. (canceled)

27. (canceled)

28. The heat spreader according to claim 25, comprising frame grooves formed in an interior surface of the frame spacer to facilitate wicking of condensate between the first body member and the second body member.

29. The heat spreader according to claim 28, comprising spacers disposed between the first body member and the second body member to maintain a spacing of the first body member from the second body member, and wherein the spacers include spacer grooves formed on surfaces thereof to facilitate wicking of the condensate between the first body member and the second body member.

30. (canceled)
